(19) United States
(12) Patent Application Publication
(10) Pub. No.: US 2011/0034007 A1
(43) Pub. Date: Feb. 10, 2011

(54) DIVIDING METHOD FOR PLATELIKE WORKPIECE

(75) Inventors: Yoshiaki Yodo, Ota-Ku (JP); Masaru Nakamura, Tokyo (JP)

Correspondence Address: GREER, BURNS & CRAIN, 300 S WACKER DR, 25TH FLOOR, CHICAGO, IL, 60606, US

(73) Assignee: DISCO CORPORATION, Tokyo (JP)

(21) Appl. No.: 12/837,235

(22) Filed: Jul. 15, 2010

(30) Foreign Application Priority Data
Aug. 4, 2009 (JP) 2009-181439

(51) Int. Cl. H01L 21/304

(52) U.S. Cl. 438/463; 257/E21.237

(57) ABSTRACT

A dividing method for a platelike workpiece having a two-layer structure such that a solder layer (metal layer) is formed on the back side of a wafer (substrate). First, a modified layer is formed in the wafer along each division line formed on the front side of the wafer. Thereafter, the workpiece is bent along each division line to thereby divide the wafer along each division line from the corresponding modified layer as a starting point and simultaneously form a weak portion in the solder layer along each division line. Thereafter, an expandion tape attached to the solder layer is expanded to apply an external force to the solder layer, thereby dividing the solder layer along each division line from the corresponding weak portion as a starting point. Thus, the workpiece is completely divided.

### BACKGROUND OF THE INVENTION

1. Field of the Invention

The present invention relates to a method of dividing a workpiece into a plurality of chips, wherein the workpiece is composed of a substrate such as a semiconductor wafer and a metal layer such as a solder layer formed on one side of the substrate.

2. Description of the Related Art

In a semiconductor device fabrication process, a plurality of crossing division lines are formed on the front side of a disk-shaped semiconductor wafer to partition a plurality of rectangular regions where electronic circuits such as ICs and LSIs are respectively formed. After grinding the back side of the semiconductor wafer and next polishing the ground surface of the semiconductor wafer as required, the semiconductor wafer is cut along all of the division lines, that is, dicing of the semiconductor wafer is performed, thereby obtaining a plurality of semiconductor chips. In general, dicing of the semiconductor wafer is performed by using a cutting apparatus such that a cutting blade rotating at a high speed is fed into the semiconductor wafer held on a chuck table (see Japanese Patent Laid-open No. Hei 8-25209, for example).

As another method of dividing a semiconductor wafer, a laser processing method has been attempted in recent years, wherein a laser beam is applied to the wafer so as to be focused inside the wafer. In such a dividing method using laser processing, a pulsed laser beam having a transmission wavelength in an infrared region is applied from one side of a semiconductor wafer so as to be focused inside the wafer, thereby continuously forming a modified layer in the wafer along each division line. Thereafter, an external force is applied to the wafer along each division line where the strength has been reduced by the formation of each modified layer, thereby breaking the wafer along each division line (see Japanese Patent No. 3408805, for example). Known as means for applying an external force to the wafer is means for expanding an adhesive tape such as a protective tape attached to the back side of a semiconductor wafer to thereby pull the semiconductor wafer in its radial direction (see Japanese Patent Laid-open No. 2007-27250, for example).

### SUMMARY OF THE INVENTION

Each semiconductor chip divided from the semiconductor wafer is mounted on a printed board or the like. There is a case that soldering is adopted as fixing means in mounting each semiconductor chip on the printed board. In the case of soldering each semiconductor chip to the printed board, a solder layer must be formed on the back side of each semiconductor chip as a mount surface. Accordingly, the solder layer is formed on the back side of the semiconductor wafer before dividing the semiconductor wafer into the individual semiconductor chips. However, in the case of dividing the semiconductor wafer having the solder layer on the back side by applying a laser beam and next applying an external force as mentioned above, it is difficult to divide the solder layer because of its high tenacity.

It is therefore an object of the present invention to provide a dividing method for a platelike workpiece having a metal layer such as a solder layer formed on a substrate, which can divide the workpiece by applying a laser beam to the substrate and next applying an external force to the workpiece.

In accordance with an aspect of the present invention, there is provided a method of dividing a platelike workpiece along a plurality of division lines formed on the front side of a substrate, wherein the front side of the substrate is partitioned into a plurality of chip regions by the division lines, and a metal layer is formed on the back side of the substrate, the method, including a modified layer forming step of applying a laser beam having a transmission wavelength to the substrate along the division lines so that the laser beam is focused inside the substrate, thereby forming a modified layer in the substrate along each division line; an expansion tape attaching step of attaching an expansion tape to the metal layer of the workpiece before or after performing the modified layer forming step; a bending step of bending the workpiece along each division line toward the metal layer side after performing the modified layer forming step and the expansion tape attaching step, thereby dividing the substrate along each division line from the corresponding modified layer as a starting point and simultaneously forming a weak portion in the metal layer along each division line; and an expansion tape expanding step of expanding the expansion tape after performing the bending step, thereby dividing the metal layer along each division line from the corresponding weak portion as a starting point.

In accordance with another aspect of the present invention, there is provided a method of dividing a platelike workpiece along a plurality of division lines formed on the front side of a substrate, wherein the front side of the substrate is partitioned into a plurality of chip regions by the division lines, and a metal layer is formed on the back side of the substrate, the method, including a modified layer forming step of applying a laser beam having a transmission wavelength to the substrate along the division lines so that the laser beam is focused inside the substrate, thereby forming a modified layer in the substrate along each division line; an expansion tape attaching step of attaching an expansion tape to the substrate of the workpiece before or after performing the modified layer forming step; a bending step of bending the workpiece along each division line toward the substrate side after performing the modified layer forming step and the expansion tape attaching step, thereby dividing the substrate along each division line from the corresponding modified layer as a starting point and simultaneously forming a weak portion in the metal layer along each division line; and an expansion tape expanding step of expanding the expansion tape after performing the bending step, thereby dividing the metal layer along each division line from the corresponding weak portion as a starting point.

According to each method of the present invention, in the bending step, the substrate is divided along each division line from the corresponding modified layer as a starting point, and the weak portion is formed in the metal layer along each division line. In the next expansion tape expanding step, the metal layer is divided along each division line from the corresponding weak portion as a starting point. Thus, the substrate and the metal layer can be reliably divided along each division line by performing bending and expansion.

The substrate used in the present invention is not especially limited. Examples of the substrate may include a semiconductor wafer such as a silicon wafer, a semiconductor product package, a substrate of ceramic, glass, or silicon containing material, and various work materials required to ensure an accuracy on the order of micrometers.

According to the present invention, after applying a laser beam to the substrate to form the modified layer in the substrate, a first external force is applied to the workpiece in the bending step and a second external force is next applied to the workpiece in the expanding step. Accordingly, the platelike workpiece having the metal layer can be reliably divided.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1A is a perspective view of a workpiece having a solder layer formed on the back side of a semiconductor wafer;

FIG. 1B is a perspective view of the workpiece in the condition where an expansion tape is attached to the solder layer;

FIG. 2A is a sectional side view showing an expansion tape attaching step according to a preferred embodiment of the present invention;

FIG. 2B is a sectional side view showing a modified layer forming step according to this preferred embodiment;

FIG. 2C is a sectional side view showing a bending step according to this preferred embodiment;

FIG. 2D is a sectional side view showing an expansion tape expanding step according to this preferred embodiment;

FIGS. 3A and 3B are sectional side views showing the sequential steps of a method of bending the workpiece as an example of the bending step shown in FIG. 2C;

FIG. 4 is an enlarged view of an enclosed area IV in FIG. 2C;

FIG. 5A is a sectional side view showing a bending step according to another preferred embodiment of the present invention;

FIG. 5B is a sectional side view showing an expansion tape expanding step to be performed after the bending step shown in FIG. 5A; and

FIG. 6 is an enlarged view of an enclosed area VI in FIG. 5A.

### DETAILED DESCRIPTION OF THE PREFERRED EMBODIMENTS

There will now be described preferred embodiments of the present invention with reference to the drawings.

### (1) Workpiece

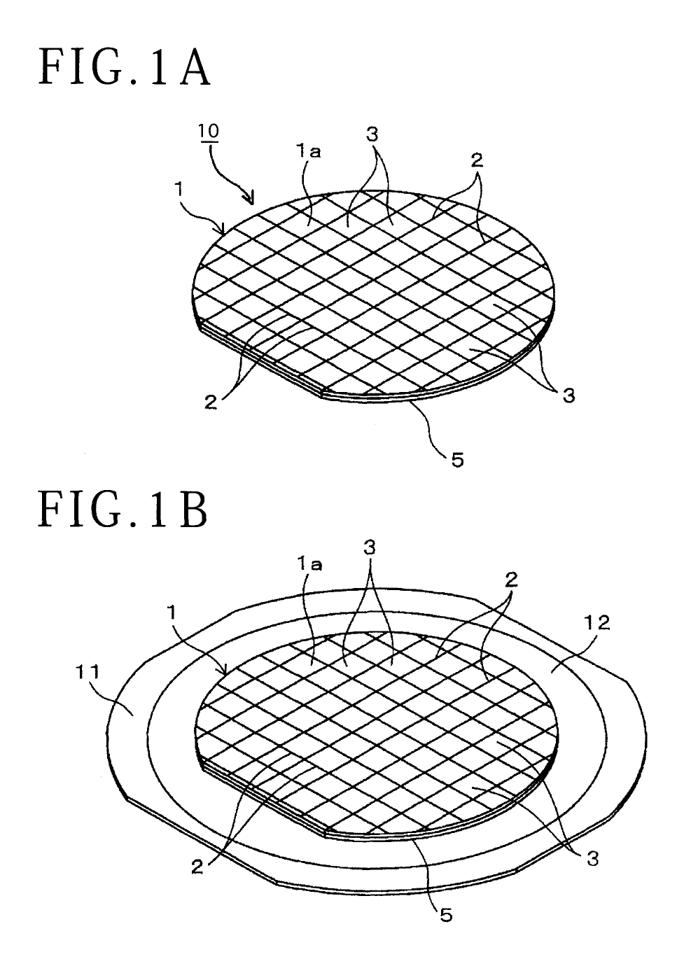

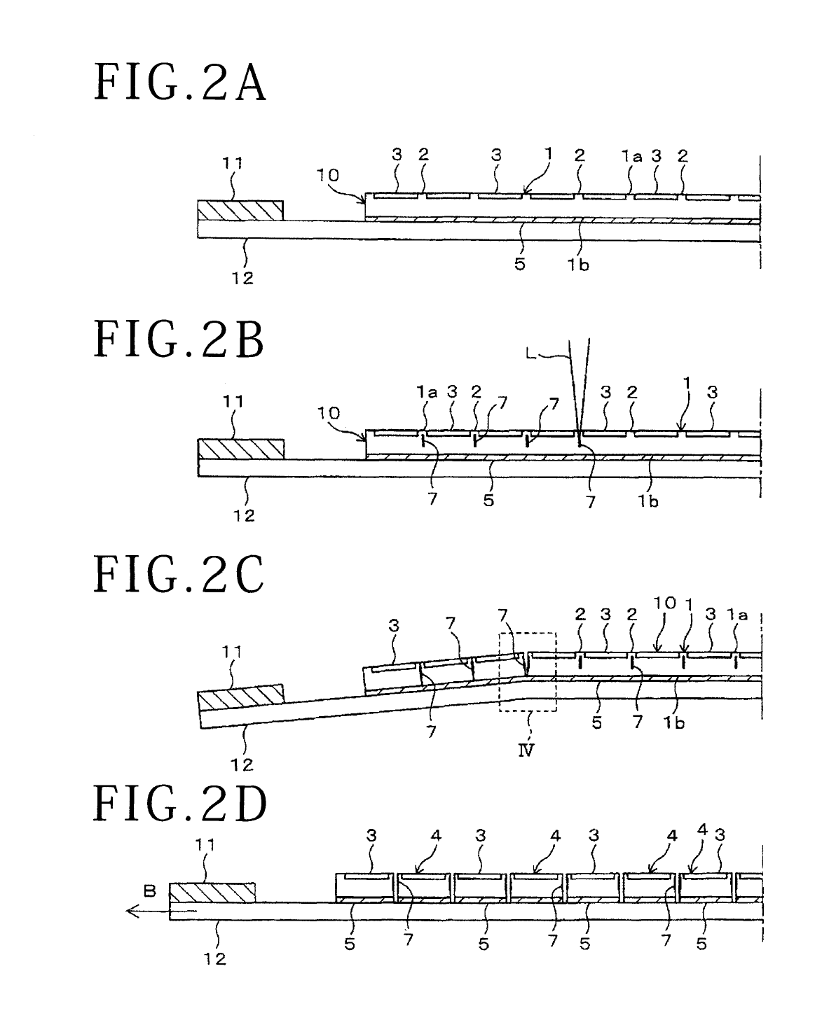

Reference numeral 10 in FIGS. 1A and 2A denotes a workpiece in this preferred embodiment. The workpiece 10 has a two-layer structure such that a solder layer (metal layer) 5 is formed on the back side 1b of a disk-shaped semiconductor wafer (substrate, which will be hereinafter referred to simply as wafer) 1. The wafer 1 is a silicon wafer, for example. A plurality of rectangular devices (chip regions) 3 partitioned by a plurality of crossing division lines 2 are formed on the front side 1a of the wafer 1. An electronic circuit such as IC and LSI (not shown) is formed on the front side of each device 3. The thickness of the solder layer 5 is set to several micrometers to tens of micrometers, for example. The solder layer 5 may be formed by any means for forming a thin film from an alloy material for solder, such as an evaporation or sputtering apparatus.

This preferred embodiment provides a method of dividing the workpiece 10 along the division lines 2 to obtain a plurality of semiconductor chips each having the device 3 on the front side and the solder layer 5 on the back side. The steps of this method will now be described.

### (2) Steps of the Dividing Method

(2-1) Expansion Tape Attaching Step

As shown in FIGS. 1B and 2A, a circular expansion tape 12 supported to an annular frame 11 is attached to the solder layer 5 of the workpiece 10. The expansion tape 12 is composed of an expandable base sheet (e.g., synthetic resin sheet of polyvinyl chloride, polypropylene, polyethylene, polyolefin, etc.) and an adhesive layer formed on one side of the expandable base sheet. The frame 11 is preliminarily attached to the adhesive layer of the expansion tape 12. The workpiece 10 is concentrically positioned inside of the frame 11 and attached to the adhesive layer of the expansion tape 12. The frame 11 is formed from a rigid plate of metal or the like, and this rigid frame 11 is handled in transporting the workpiece 10.

(2-2) Modified Layer Forming Step

As shown in FIG. 2B, a laser beam L having a transmission wavelength to the wafer 1 (e.g., pulsed laser beam having a wavelength of 1064 nm) is applied along the division lines 2 so as to be focused inside the wafer 1, thereby forming a continuous modified layer 7 along each division line 2. By forming the modified layer 7 along each division line 2, the strength of the wafer 1 is reduced along each division line 2. The order of the modified layer forming step and the expansion tape attaching step is arbitrary. That is, the expansion tape attaching step may be performed after the modified layer forming step.

(2-3) Bending Step

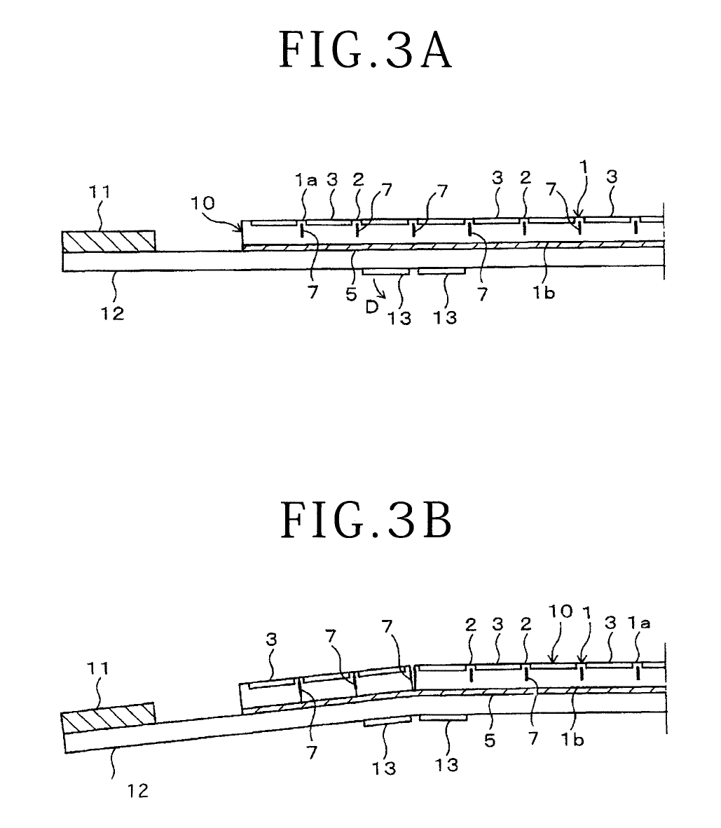

After performing the modified layer forming step, the workpiece 10 is bent along each division line 2 toward the solder layer 5 side as shown in FIG. 2C. For example, bending of the workpiece 10 along each division line 2 may be performed by placing a straight edge (e.g., edge of a plate) on the back side of the workpiece 10 at a position corresponding to each division line 2 and next applying an external force to the workpiece 10 so that the workpiece 10 is bent toward the solder layer 5 side. Another method is shown in FIGS. 3A and 3B, wherein two suction plates 13 are set on the lower surface of the expansion tape 12 at positions corresponding to the adjacent devices 3, and one of the two suction plates 13 (e.g., the left one in FIGS. 3A and 3B) is rotated in the direction of an arrow D in FIG. 3A, thereby bending the workpiece 10 along each division line 2.

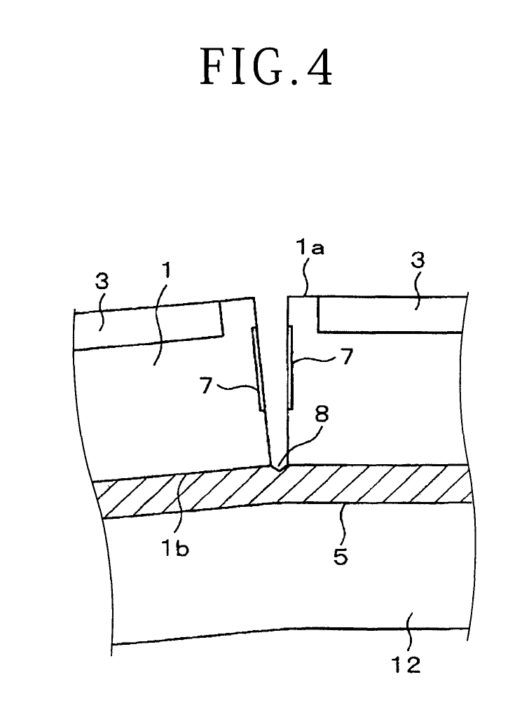

When the workpiece 10 is bent along each division line 2 toward the solder layer 5 side, the wafer 1 starts to be broken from the modified layer 7 formed in the wafer 1 along each division line 2 as shown in FIG. 4. However, the solder layer 5 is not yet broken, but a weak portion 8 due to a groove or crack is formed in the solder layer 5 along each division line 2. In this bending step, the workpiece 10 is bent along all of the division lines 2 to thereby form the weak portions 8 in the solder layer 5 at the positions corresponding to all of the division lines 2. The degree of bending (bending angle) of the workpiece 10 must be set so that the weak portions 8 are reliably formed in the solder layer 5.

(2-4) Expansion Tape Expanding Step

As shown in FIG. 2D, the expansion tape 12 is expanded in the radial direction shown by an arrow B. When the expansion tape 12 is thus expanded in the radial direction, the solder layer 5 attached to the expansion tape 12 is subjected to an external force of pulling the solder layer 5 in the radial direction. Accordingly, the solder layer 5 starts to be broken from the weak portions 8 formed in the bending step. In this stage, the workpiece 10 is completely divided along all of the division lines 2 to obtain a plurality of semiconductor chips 4. Each semiconductor chip 4 has the device 3 on the front side and the solder layer 5 on the back side. This expansion tape expanding step may be performed by using the apparatus described in Japanese Patent Laid-open No. 2007-27250 cited above.

In this stage, each semiconductor chip 4 divided from the workpiece 10 remains attached to the expansion tape 12. In a subsequent pickup step (not shown), each semiconductor chip 4 is picked up from the expansion tape 12. For example, each semiconductor chip 4 is pushed up from the solder layer 5 side to avoid damage to each device 3. Accordingly, this pickup step can be performed in the condition where each semiconductor chip 4 remains attached to the expansion tape 12 as shown in FIG. 2D after performing the expansion tape expanding step. That is, each semiconductor chip 4 is pushed up from the expansion tape 12 side and next peeled off from the expansion tape 12. Thereafter, each semiconductor chip 4 thus picked up is mounted on a printed board or the like by soldering through the solder layer 5.

### (3) Operation and Meritorious Effects

According to the dividing method in this preferred embodiment, in the bending step as a first stage, the wafer 1 of the workpiece 10 is broken along each division line 2 from the corresponding modified layer 7 as a starting point, and the weak portion 8 is formed in the solder layer 5 at a position corresponding to each division line 2. Thereafter, in the expansion tape expanding step as a second stage, the solder layer 5 is broken along each division line 2 from the corresponding weak portion 8 as a starting point. Thus, the workpiece 10 is divided by bending and expansion, so that the workpiece 10 having a two-layer structure can be divided reliably in contrast to the case that the expansion tape 12 is simply expanded and the workpiece 10 is therefore difficult to reliably divide.

### (4) Another Preferred Embodiment

Another preferred embodiment of the present invention will now be described.

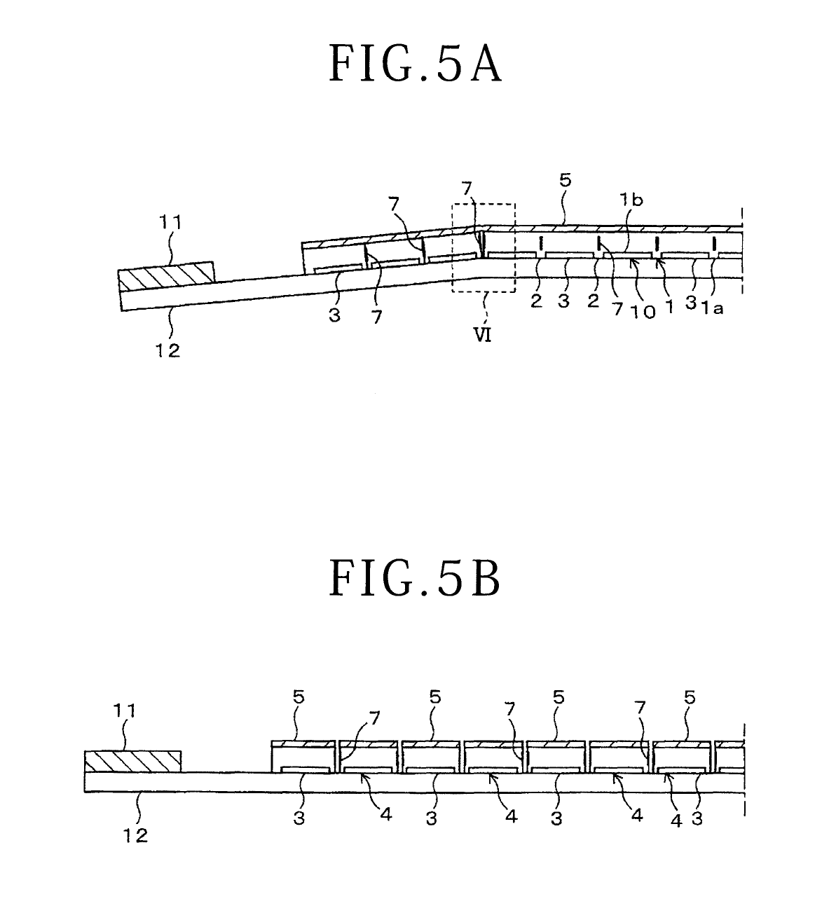

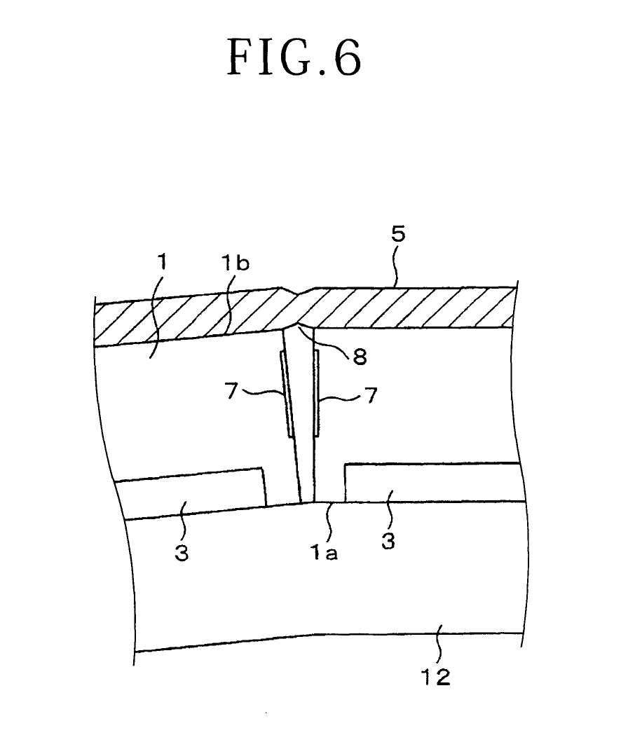

In the above preferred embodiment, the bending step is performed in the condition where the expansion tape 12 is attached to the solder layer 5 of the workpiece 10. As another preferred embodiment of the present invention, the bending step may be performed in the condition where the expansion tape 12 is attached to the wafer 1 rather than the solder layer 5. The attachment of the expansion tape 12 to the wafer 1 may be performed before or after the modified layer forming step. After performing the modified layer forming step, the workpiece 10 is bent along each division line 2 toward the wafer 1 side where the expansion tape 12 is attached as shown in FIG. 5A. Accordingly, as shown in FIG. 6, the wafer 1 of the workpiece 10 is broken along each division line 2 from the corresponding modified layer 7 as a starting point, and a weak portion 8 due to a groove or crack is formed in the solder layer 5 at a position corresponding to each division line 2.

In this manner, the workpiece 10 is bent along all of the division lines 2 toward the wafer 1 side to thereby break the wafer 1 and form the weak portion 8 in the solder layer 5 along each division line 2. Thereafter, the expansion tape expanding step is performed as in the previous preferred embodiment. Accordingly, as shown in FIG. 5B, the solder layer 5 is broken along each division line 2 from the corresponding weak portion 8 as a starting point. As a result, the workpiece 10 is completely divided along each division line 2 to obtain a plurality of semiconductor chips 4.

In this preferred embodiment, the solder layer 5 not attached to the expansion tape 12 is located outside of the bending portion of the workpiece 10, i.e., apart from the starting point of bending. Accordingly, tensile stress can be effectively produced in the solder layer 5 in bending the workpiece 10. As a result, the strength of each weak portion 8 in the solder layer 5 can be reduced, so that in some cases the solder layer 5 can be cut or almost cut in the bending step. Further, in the expansion tape expanding step, the solder layer 5 is expanded in a floating condition where it is not attached to the expansion tape 12. As a result, the workpiece 10 can be easily divided in the expansion tape expanding step.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A method of dividing a platelike workpiece along a plurality of division lines formed on the front side of a substrate, wherein the front side of said substrate is partitioned into a plurality of chip regions by said division lines, and a metal layer is formed on the back side of said substrate, said method, comprising:
a modified layer forming step of applying a laser beam having a transmission wavelength to said substrate along said division lines so that said laser beam is focused inside said substrate, thereby forming a modified layer in said substrate along each division line;
an expansion tape attaching step of attaching an expansion tape to said metal layer of said workpiece before or after performing said modified layer forming step;
a bending step of bending said workpiece along each division line toward said metal layer side after performing said modified layer forming step and said expansion tape attaching step, thereby dividing said substrate along each division line from the corresponding modified layer as a starting point and simultaneously forming a weak portion in said metal layer along each division line; and
an expansion tape expanding step of expanding said expansion tape after performing said bending step, thereby dividing said metal layer along each division line from the corresponding weak portion as a starting point.

2. A method of dividing a platelike workpiece along a plurality of division lines formed on the front side of a substrate, wherein the front side of said substrate is partitioned into a plurality of chip regions by said division lines, and a metal layer is formed on the back side of said substrate, said method, comprising:
a modified layer forming step of applying a laser beam having a transmission wavelength to said substrate along said division lines so that said laser beam is focused inside said substrate, thereby forming a modified layer in said substrate along each division line;
an expansion tape attaching step of attaching an expansion tape to said substrate of said workpiece before or after performing said modified layer forming step;
a bending step of bending said workpiece along each division line toward said substrate side after performing said modified layer forming step and said expansion tape attaching step, thereby dividing said substrate along each division line from the corresponding modified layer as a starting point and simultaneously forming a weak portion in said metal layer along each division line; and
an expansion tape expanding step of expanding said expansion tape after performing said bending step, thereby dividing said metal layer along each division line from the corresponding weak portion as a starting point.
